(19) United States
(12) Patent Application Publication
(10) Pub. No.: US 2006/0249844 A1
(43) Pub. Date: Nov. 9, 2006

(54) Contact structure on chip and package thereof

(75) Inventor: Chih-An Yang, Shindian City (TW)

Correspondence Address: BIRCH STEWART KOLASCH & BIRCH, PO BOX 747, FALLS CHURCH, VA, 22040-0747, US

(73) Assignee: VIA TECHNOLOGIES, INC.

(21) Appl. No.: 11/224,126

(22) Filed: Sep. 13, 2005

(30) Foreign Application Priority Data
May 6, 2005 (TW) 094114629

(51) Int. Cl. H01L 23/48

(52) U.S. Cl. 257/737; 257/778

(57) ABSTRACT

A contact structure on a chip is disclosed. The contact is disposed on a metallic pad of the chip. The contact structure includes a bump and a buffer layer. The bump is disposed on the metallic pad. The buffer layer is disposed on the chip to surround the interface between the bump and the metallic pad. A weakest inter-metallic compound naturally formed between the metallic pad and the bump will be protected by the buffer layer and far away from the stress concentration point for increasing the reliability of a flip chip package.

### BACKGROUND OF THE INVENTION

1. Field of Invention

The present invention relates to a flip chip package, and in particular, to a contact structure on a chip and a flip chip package.

2. Related Art

Due to rapid development of semiconductor device and process, semiconductor integration circuits or semiconductor chips have powerful functionality and are widespread applied to electronic devices. The chip is well-protected by a package process to provide high reliability and elastic electrical connection suitable for fitting a variety of requirements. Flip chip package is one of popular packaging types. However, package material with limitative lead concentration or even without lead will gradually become an inexorable trend based on environmental protection because lead is identified as harmful to brain development especially to babies and kids.

FIG. 1 shows a conventional contact structure of a flip chip package. A plurality of die pads 112 and a passivation layer 113 are disposed on an active surface of a chip 111. The passivation layer 113 is covered the active surface of the chip 111 and has a plurality of openings to respectively expose the die pads 112. The die pads 112 are made of metal and are electrically connected to power terminals, ground terminals, or signal terminals of the chip 111. In order for connecting the die pads 112 to outside, an under bump metallurgy (UBM) 121 and a bump 123 are sequentially disposed on a die pad 112. The connection between the bump 123 and the die pad 112 needs to be performed by the UBM 121 because the bump 123 and the die pad 112 cannot bind well due to the different material property. For instance, the bump 123 is a tin-copper-silver solder and the die pad 112 is made of aluminum-copper alloy, and the UBM 121 is a titanium-copper-nickel alloy to be the connecting interface between the bump 123 and the die pad 112.

The chip 111 embedded the bumps 123 is further disposed on a package substrate 131 to electrically connect to the other elements on or within the package substrate 131. The package substrate 131 has a plurality of bump pads 132 in correspondence with the bumps 123 one-to-one. In other words, one bump pad 132 of the package substrate 131 is respectively corresponding to one bump 123. The surface of the package substrate 131 is covered by a solder mask layer 133 for protecting the circuits thereunder. The solder mask layer 133 has a plurality of openings to respectively expose the bump pads 132 connected to the bumps 123. In order for facilitating the electrical connection between the bumps 123 and the bump pads 132, a pre-solder 134 is respectively disposed on the bump pads 132. The pre-solder 134 is connected to the bump 123 and the pre-solder 134 is connected to the bump pad 132 by a thermal and pressurized process. This process is so-called a soldering process.

Because of the advantages of high electric property, plenty of terminals and high density arrangement, flip chip packaging is still widespread applied. However, flip chip package will sometimes occur electrical disconnection especially under long terms usage or high temperature testing, and reduce the product reliability.

Under the circumstances of long terms of usage or high temperature condition, the interface between the UBM 121 and the bump 123 will gradually react and produce an inter-metallic compound (IMC) 122. For instance, the bump 123 is a tin-copper-silver solder and the UBM 121 is a titanium-copper-nickel alloy, and the natural forming IMC 122 is a tin-copper-nickel compound. Comparing to the UBM 121 or the bump 123, the mechanical strength of the IMC 122 is weaker. The position of exterior connection between the UBM 121 and the bump 123 has an angle, which depends on molecular binding energy of the different materials. As to conventional bump material, the angle is about less than or equal to 90 degree. Therefore, a stress concentration point is formed at the position of exterior connection between the UBM 121 and the bump 123. Because different materials respectively have different coefficients of thermal expansion, a thermal stress at the exterior connection will cause a material fatigue during the chip is used. Under long terms of usage or high temperature condition, the interface between the UBM 121 and the bump 123 is easily electrical disconnected.

FIG. 2 shows another conventional contact structure of a flip chip package. A plurality of die pads 112a and a passivation layer 113 are disposed on an active surface of a chip 111a. A stud bump 123a is respectively electroplated on the die pad 112a. For instance, the die pad 112a is a metal containing copper with a gold containing coating. The stud bump 123a is made of metal selected from the group consisting of copper, silver, gold, nickel, tin, zinc, aluminum and the combination. Similarly, a IMC 122a is natural formed between the stud bump 123a and the die pad 112a, and is easily electrical disconnected by stress concentration.

Although flip chip package has excellent advantages and is widespread applied to electronic devices, however the natural formation IMC between the UBM 121 or the bump 123 or between the die pad 112a and the stud bump 123a will seriously affect the reliability and lifetime of flip chip package.

It is therefore an important subject of the present invention to provide a contact structure on a chip and a flip chip package to solve above-mentioned problems.

### SUMMARY OF THE INVENTION

In view of the foregoing, the present invention is to provide a contact structure on a chip and a flip chip package for increasing the reliability of the flip chip package.

To achieve the above aspect, a contact structure according to the present invention is disposed on a metallic pad on a chip. The contact structure comprises a bump and a buffer layer. The metallic pad comprises a die pad disposed on the chip or further comprises an under-bump metallic layer disposed on the die pad. The bump is disposed on the metallic pad. The buffer layer is disposed on the chip to surround the interface between the bump and the metallic pad. A weakest inter-metallic compound naturally formed between the metallic pad and the bump will be protected by the buffer layer and far away from the stress concentration point for increasing the reliability of a flip chip package.

To achieve the above aspect, a flip chip package according to the present invention comprises a chip and a package substrate. A plurality of metallic pads disposed on the chip are covered by a passivation layer. The passivation layer has a plurality of openings to respectively expose the metallic pads. A plurality of contact structures are respectively connected to the metallic pads. The contact structure comprises a bump and a buffer layer. The bump is disposed on the metallic pad. The buffer layer is disposed on the passivation layer to surround the interface between the bump and the metallic pad. A plurality of bump pads disposed on the package substrate are respectively electrically connected to the bumps.

As mentioned above, due to the buffer layer is disposed surrounding the interface between the bump and the metallic pad, the interface of a contact structure on a chip and a flip chip package according to the present invention will be protected by the buffer layer and far away from the stress concentration point for increasing the reliability of a flip chip package.

### BRIEF DESCRIPTION OF THE DRAWINGS

The present invention will become more fully understood from the detailed description given herein below illustration only, and thus is not limitative of the present invention, and wherein:

FIG. 1 is a schematic view showing a conventional contact structure of a flip chip package;

FIG. 2 is a schematic view showing another conventional contact structure of a flip chip package;

FIGS. 3A to 3D are process flows showing the manufacture of a contact structure on a chip according to the present invention;

FIG. 4 is a schematic view showing a contact structure of a flip chip package according to the present invention; and

FIG. 5 is a schematic view showing another contact structure of a flip chip package according to the present invention.

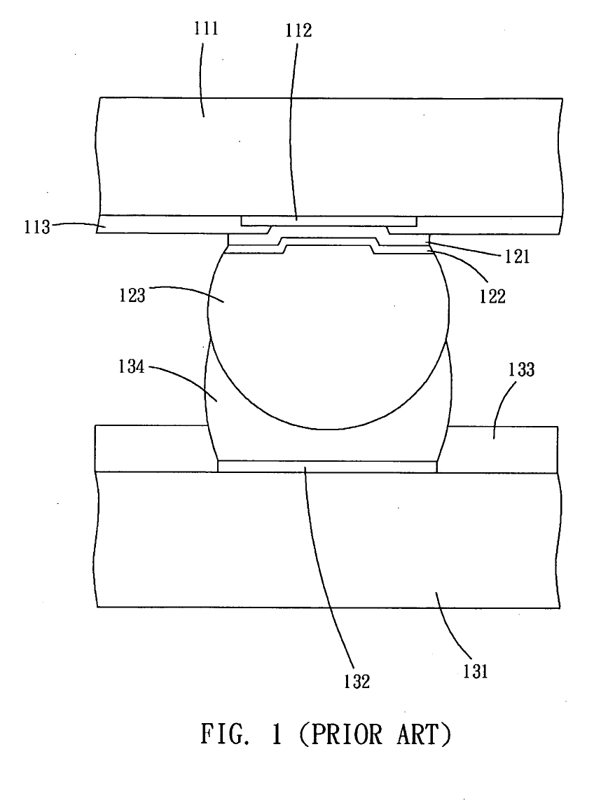

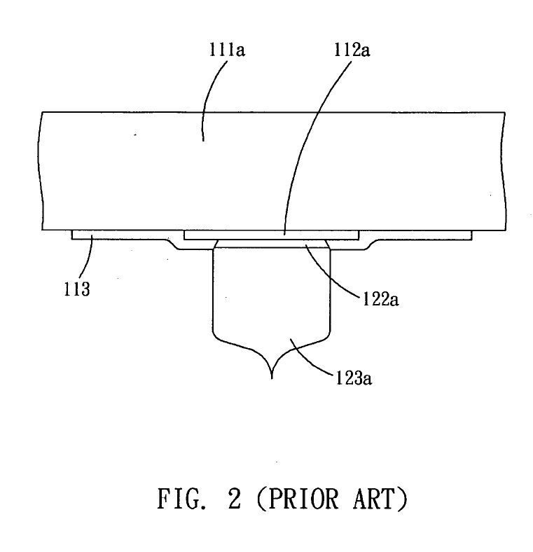

### DETAILED DESCRIPTION OF THE INVENTION

The present invention will be apparent from the following detailed description, which proceeds with reference to the accompanying drawings, wherein the same references relate to the same elements. The present invention is not limitative to the following process.

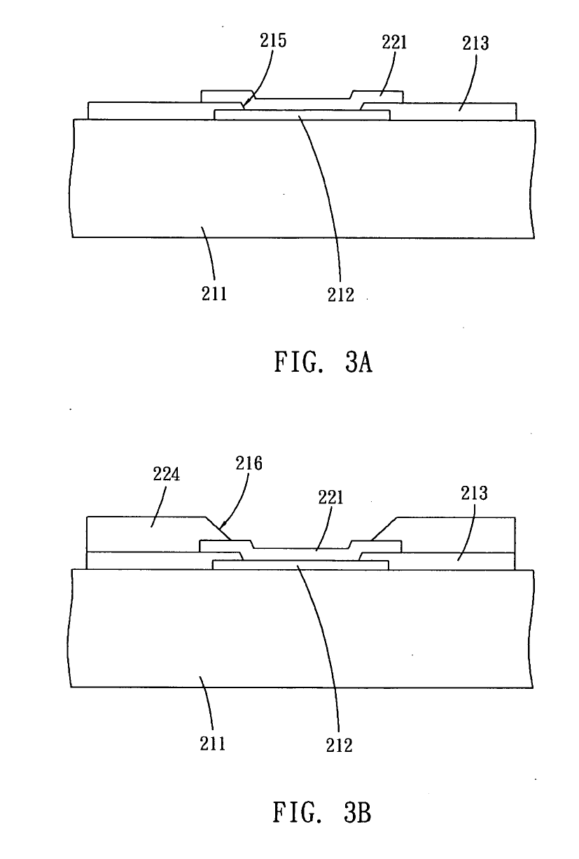

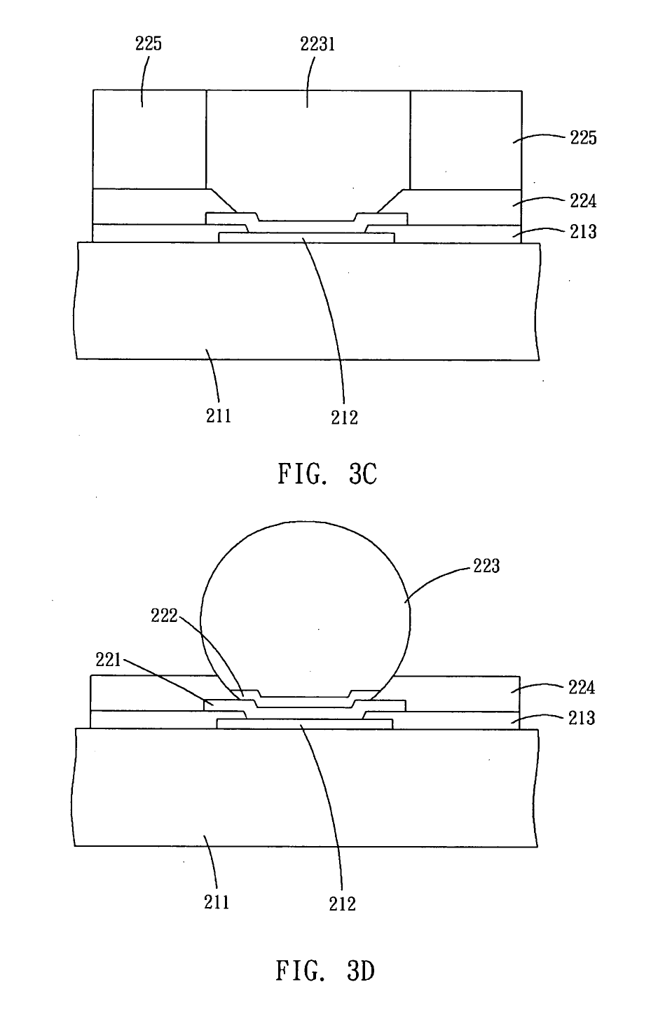

As shown in FIG. 3A, the manufacturing process of a contact structure on a chip according to the present invention includes the following steps. Firstly, providing a chip 211, a plurality of die pads 212 and a passivation layer 213 are sequentially formed on an active surface of the chip 211. The chip 211 is electrically connected to outside such as a package substrate by the die pads 212. The passivation layer 213 is covered on the chip 211 and the die pads 212 to protect the circuit thereunder. The material of the passivation layer 213 includes oxide, nitride or oxy-nitride of the chip substrate. For instance, the chip 211 is a silicon substrate, the passivation layer 213 is made of silicon oxide. The passivation layer 213 has a plurality of first openings 215 to respectively expose the die pads 212. An under-bump metallic layer 221 is formed on the die pad 212 and is covered a portion of the passivation layer 213 around the first opening 215.

As shown in FIG. 3B, forming a buffer layer 224 on the passivation layer 213 and the under-bump metallic layer 221. The thickness of the buffer layer 224 is greater than that of the under-bump metallic layer 221. The buffer layer 224 further has a plurality of second openings 216 to respectively expose the under-bump metallic layer 221. The second openings 216 are formed by photolithography and etching processes. The material of the buffer layer 224 includes epoxy, polyimide or benzocyclobutene (BCB). The forming method for the second openings 216 is such as plasma etching.

FIG. 3C shows forming a bump material 2231 on the under-bump metallic layer 221. Firstly, forming a photoresist layer 225 on the buffer layer 224, then removing a portion of the photoresist layer 225 on the under-bump metallic layer 221 after exposure and development processes. Then, forming the bump material 2231 on the under-bump metallic layer 221. As shown in FIG. 3D, removing the photoresist layer 225 and reflowing the bump material 2231 to be a bump 223. Due to surface tension of the bump material 2231, the bump 223 is formed as a ball bump. The bump 223 may be made of solder with lead (such as lead-tin alloy) or solder without lead (such as tin-copper-silver alloy).

The interface between the bump 223 and the under-bump metallic layer 221 is naturally formed an inter-metallic compound (IMC) 222. The thickness of the buffer layer 224 is greater than them of the under-bump metallic layer 221 and the inter-metallic compound 222. The mechanical strength of the inter-metallic compound 222 is weak as shown in the prior art. However, the buffer layer 224 disposed on the passivation layer 213 surrounds the interface between the bump 223 and the under-bump metallic layer 221. The stress concentration point of the bump 223 caused by geometrical variation will be released to the interface between the bump 223 and the buffer layer 224. That is, by adjusting the diameter and tilted angle of the second opening 216, the stress is released to the interface between the bump 223 and the buffer layer 224. Due to the buffer layer 224 may share the stress, and lifetime and reliability of the contact structure of a flip chip package are improved.

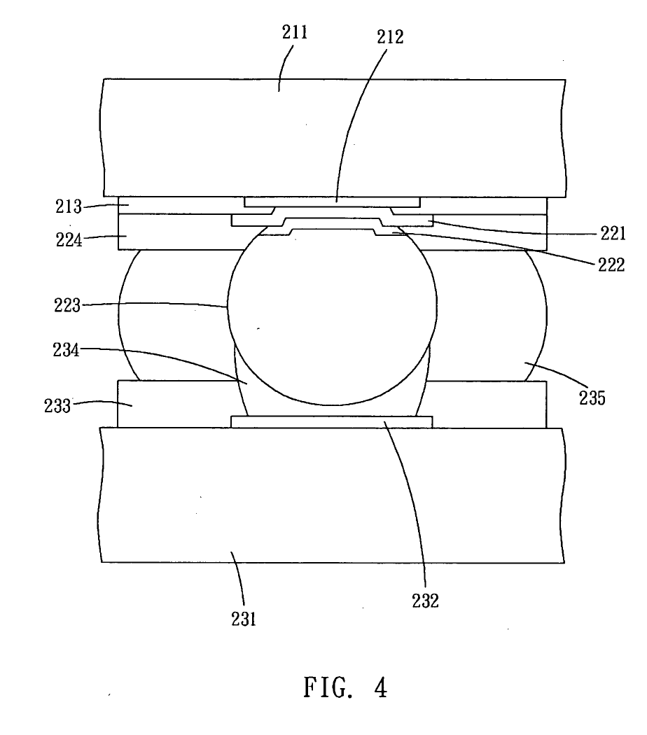

As shown in FIG. 4, a flip chip package according to the present invention includes the chip 211 and a package substrate 231. A plurality of bump pads 232 are disposed on the package substrate 231 and are electrically connected to the bumps 223 on the chip 211 one-to-one. The package substrate 231 may further include a solder-mask layer 233 covering the package substrate 231 and the bump pads 232 to protect the circuit thereunder. The solder-mask layer 233 has a corresponding opening to the bump pad 232 to expose the bump pad 232. In order for forming the connection between the bump pad 232 and the bump 223, a pre-solder material 234 is formed on the exposed bump pad 232. The chip 211 with the bump 223 is then covered onto the package substrate 231 in alignment. The pre-solder material 234 is connected with the bump 223 and the bump pad 232 after a thermal and pressurized process. This process is so-called a soldering process. The chip 211 and the package substrate 231 are thus electrically connected. In order for protecting the electrical connection structure from chemicals and moisture, an underfill material 235 may be further filled into the gap between the chip 211 and the package substrate 231.

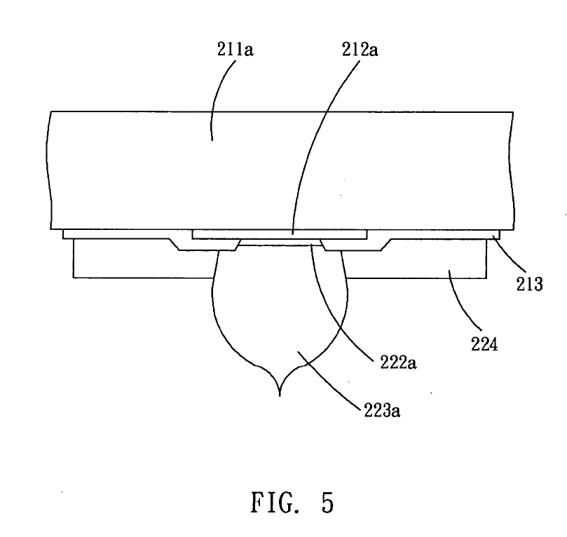

FIG. 5 shows another contact structure of a flip chip package according to the present invention. A plurality of die pads 212a disposed on a chip 211a are covered by a passivation layer 213. A stud bump 223a is disposed on the die pad 212a. The interface between the stud bump 223a and the die pad 212a is naturally formed an inter-metallic compound 222a. A buffer layer 224 disposed on the chip 211a surrounds the interface between the stud bump 223a and the die pad 212a. The thickness of the buffer layer 224 is greater than that of the inter-metallic compound 222a. The chip 211a with the stud bump 223a is further connected with a package substrate in alignment to form a flip chip package. Due to the buffer layer 224 may provide an advantage of stress release, lifetime and reliability of the contact structure of a flip chip package are then improved. However, the stud bump 223a on the chip 211a and the connection with the package substrate is not limited to soldering. The bump may be connected to the package substrate by an anisotropic conductive film (ACF) without leaving the scope and spirit of the present invention for those skilled in this art.

In summary, due to the buffer layer is disposed surrounding the interface between the bump and the metallic pad, the stress concentration point of the bump caused by geometrical variation will be released to the interface between the bump and the buffer layer. By adjusting the diameter and tilted angle of the opening of the buffer layer, the stress is released and not concentrated on the interface between the bump and the metallic pad. Thus, a contact structure on a chip and a flip chip package according to the present invention will be protected by the buffer layer and far away from the stress concentration point for increasing the reliability of a flip chip package.

Although the present invention has been described with reference to specific embodiments, this description is not meant to be construed in a pivoting sense. Various modifications of the disclosed embodiments, as well as alternative embodiments, will be apparent to persons skilled in the art. It is, therefore, contemplated that the appended claims will cover all modifications that fall within the true scope of the present invention.

What is claimed is:

1. A contact structure on a chip, at least one die pad disposed on the chip is covered by a passivation layer, the passivation layer has at least one opening to expose the die pad, the contact structure comprising:
an under-bump metallic layer, disposed on the die pad and covered a portion of the passivation layer around the opening;
a bump, disposed on the under-bump metallic layer; and
a buffer layer, disposed on the passivation layer to surround the interface between the bump and the under-bump metallic layer.

2. The contact structure on a chip according to claim 1, wherein the bump is made of solder with lead or solder without lead.

3. The contact structure on a chip according to claim 1, wherein the interface between the bump and the under-bump metallic layer is naturally formed an inter-metallic compound.

4. The contact structure on a chip according to claim 3, wherein a thickness of the buffer layer is greater than a thickness of the under-bump metallic layer and a thickness of the inter-metallic compound, such that the buffer layer provides a protection against a stress concentrating on the inter-metallic compound.

5. The contact structure on a chip according to claim 1, wherein the material of the buffer layer comprises epoxy, polyimide or BCB.

6. A contact structure on a chip, at least one die pad disposed on the chip is covered by a passivation layer, the passivation layer has at least one opening to expose the die pad, the contact structure comprising:
a bump, disposed on the die pad; and
a buffer layer, disposed on the passivation layer to surround the interface between the bump and the die pad.

7. The contact structure on a chip according to claim 6, wherein the bump is made of metal.

8. The contact structure on a chip according to claim 7, wherein the metal is at least one selected from the group consisting of copper, silver, gold, nickel, tin, zinc, aluminum and the combination.

9. The contact structure on a chip according to claim 6, wherein the interface between the bump and the die pad is naturally formed an inter-metallic compound.

10. The contact structure on a chip according to claim 9, wherein a thickness of the buffer layer is greater than a thickness of the die pad and a thickness of the inter-metallic compound, such that the buffer layer provides a protection against a stress concentrating on the inter-metallic compound.

11. The contact structure on a chip according to claim 6, wherein the material of the buffer layer comprises epoxy, polyimide or BCB.

12. A flip chip package, comprising:
a chip, a plurality of metallic pads disposed on the chip are covered by a passivation layer, the passivation layer has a plurality of openings to respectively expose the metallic pads, a plurality of contact structures are respectively connected to the metallic pads, the contact structure comprising; and
a bump, disposed on the metallic pad; and
a buffer layer, disposed on the passivation layer to surround the interface between the bump and the metallic pad;
a package substrate, a plurality of bump pads are disposed on the package substrate and are respectively electrically connected to the bumps.

13. The flip chip package according to claim 12, wherein the metallic pad comprises a die pad disposed on the chip and exposed by the opening.

14. The flip chip package according to claim 13, wherein the metallic pad further comprises an under-bump metallic layer disposed on the die pad.

15. The flip chip package according to claim 12, wherein the metal is at least one selected from the group consisting of copper, silver, gold, nickel, tin, zinc, aluminum and the combination.

16. The flip chip package according to claim 12, wherein the interface between the bump and the metallic pad is naturally formed an inter-metallic compound.

17. The flip chip package according to claim 16, wherein a thickness of the buffer layer is greater than a thickness of the metallic pad and a thickness of the inter-metallic compound, such that the buffer layer provides a protection against a stress concentrating on the inter-metallic compound.

18. The flip chip package according to claim 12, wherein the material of the buffer layer comprises epoxy, polyimide or BCB.

19. The flip chip package according to claim 12, wherein the material of the passivation layer comprises oxide, nitride or oxy-nitride.

20. The flip chip package according to claim 12, wherein the chip further comprises an under-bump metallic layer disposed on the die pad to connect the bump, and the buffer layer surrounds the interface between the bump and the under-bump metallic layer.
